(19) United States
(12) Patent Application Publication
(10) Pub. No.: US 2024/0061338 A1
(43) Pub. Date: Feb. 22, 2024

(54) RESIST UNDERLAYER COMPOSITION AND METHOD OF FORMING PATTERNS USING THE COMPOSITION

(71) Applicant: SAMSUNG SDI CO., LTD., Youngin-si (KR)

(72) Inventors: Yoojeong CHOI, Suwon-si (KR); Seongjin KIM, Suwon-si (KR); Jaeyeol BAEK, Suwon-si (KR); Hwayoung JIN, Suwon-si (KR); Soonhyung KWON, Suwon-si (KR)

(21) Appl. No.: 18/213,185

(22) Filed: Jun. 22, 2023

(30) Foreign Application Priority Data
Aug. 9, 2022 (KR) 10-2022-0099444

(51) Int. Cl. G03F 7/11; G03F 7/20

(52) U.S. Cl. CPC G03F 7/11; G03F 7/2016

(57) ABSTRACT

A resist underlayer composition and a method of forming patterns using the resist underlayer composition are provided. The resist underlayer composition may include a polymer including a structural unit represented by Chemical Formula 1, a structural unit represented by Chemical Formula 2, or a combination thereof; a compound represented by Chemical Formula 3; and a solvent.

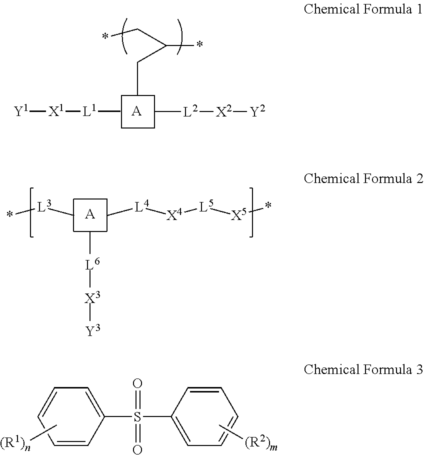

### CROSS-REFERENCE TO RELATED APPLICATION

This application claims priority to and the benefit of Korean Patent Application No. 10-2022-0099444 filed in the Korean Intellectual Property Office on Aug. 9, 2022, the entire content of which is incorporated herein by reference.

### BACKGROUND

### 1. Field

One or more embodiments of the present disclosure relate to a resist underlayer composition, and a method of forming patterns utilizing the same.

### 2. Description of the Related Art

Recently, the semiconductor industry has developed to an ultrafine technique having a pattern of several to several tens nanometer size. Such ultrafine technique essentially needs effective lithographic techniques.

The lithographic technique is a processing method including coating a photoresist layer on a semiconductor substrate such as a silicon wafer to form a thin layer, irradiating with activating radiation such as ultraviolet rays through a mask pattern on which a device pattern is drawn and then developing the resultant to obtain a photoresist pattern, and etching the substrate utilizing the photoresist pattern as a protective layer to form a fine pattern corresponding to the photoresist pattern, on the surface of the semiconductor substrate.

As semiconductor patterns are gradually refined, the photoresist layer is required to or should be thin, and accordingly, a resist underlayer is also required to or should be thin. The resist underlayer is required to or should keep the photoresist pattern despite the thinness, that is, to have a substantially uniform thickness as well as excellent or suitable close contacting property and adherence to the photoresist. In addition, the resist underlayer is required to or should be able to be efficiently patterned even at low output due to improved sensitivity to an exposure light source.

### SUMMARY

One or more aspects of embodiments of the present disclosure are directed toward a resist underlayer composition that does not cause pattern collapse of a resist even in a fine patterning process, has excellent or suitable coating uniformity, and has improved sensitivity to an exposure light source to provide a resist underlayer capable of improving patterning performance and efficiency.

One or more aspects of embodiments of the present disclosure are directed toward a method of forming patterns utilizing the resist underlayer composition.

Additional aspects will be set forth in part in the description which follows and, in part, will be apparent from the description, or may be learned by practice of the presented embodiments of the disclosure.

According to one or more embodiments, a resist underlayer composition may include a polymer including a structural unit represented by Chemical Formula 1, a structural unit represented by Chemical Formula 2, or a combination thereof; a compound represented by Chemical Formula 3; and a solvent.

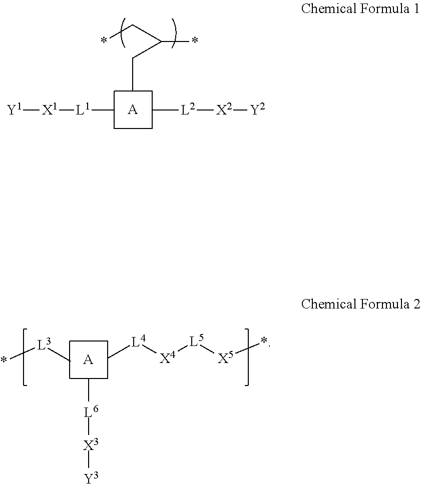

In Chemical Formula 1 and Chemical Formula 2,

A may be a cyclic group represented by any one selected from among Chemical Formula A-1 to Chemical Formula A-3,

L¹ to L⁶ may each independently be a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,

X¹ to X⁵ may each independently be a single bond, —O—, —S—, —S(═O)—, —S(═O)₂—, —C(═O)—, —(CO)O—, —O(CO)O—, —NR′— (wherein, R′ is hydrogen, deuterium, or a C1 to C10 alkyl group), or a combination thereof,

Y¹ to Y³ may each independently be a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and

* is a linking point;

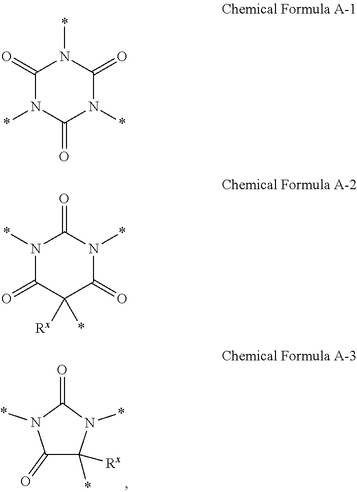

wherein, in Chemical Formula A-1 to Chemical Formula A-3,

R^{x} may be hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and

* is a linking point;

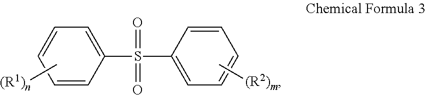

wherein, in Chemical Formula 3,

R¹ and R² may each independently be a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof, and

n and m may each independently be integers of 0 to 5.

In one or more embodiments, A of Chemical Formula 1 and Chemical Formula 2 may be represented by Chemical Formula A-1, Chemical Formula A-2, or a combination thereof.

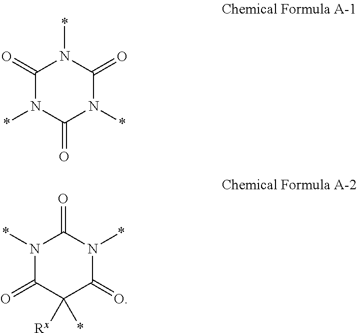

In Chemical Formula A-2, R^{x} may be hydrogen, a substituted or unsubstituted C1 to C10 alkyl group, a substituted or unsubstituted C2 to C10 alkenyl group, or a substituted or unsubstituted C2 to C10 alkynyl group, and in Chemical Formula A-1 and Chemical Formula A-2, * is a linking point.

L¹ to L⁶ of Chemical Formula 1 and Chemical Formula 2 may each independently be a single bond, a substituted or unsubstituted C1 to C10 alkylene group, a substituted or unsubstituted C1 to C10 heteroalkylene group, or a combination thereof,

X¹ to X⁵ may each independently be a single bond, —O—, —S—, —C(═O)—, —(CO)O—, —O(CO)O—, or a combination thereof, and

Y¹ to Y³ may each independently be a substituted or unsubstituted C1 to C10 alkyl group, a substituted or unsubstituted C2 to C10 alkenyl group, a substituted or unsubstituted C1 to C10 heteroalkyl group, a substituted or unsubstituted C1 to C10 heteroalkenyl group, a substituted or unsubstituted C3 to C20 cycloalkyl group, a substituted or unsubstituted C2 to C20 heterocycloalkyl group, or a combination thereof.

R¹ and R² of Chemical Formula 3 may each independently be a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, or a combination thereof.

In one or more embodiments, in Chemical Formula 3, n and m may each independently be an integer of 0 to 3.

The compound represented by Chemical Formula 3 may be represented by Chemical Formula 3-1.

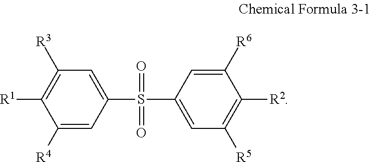

In Chemical Formula 3-1,

R¹ to R⁶ may each independently be hydrogen, a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof.

R¹ and R² of Chemical Formula 3-1 may each independently be a hydroxy group, an amino group, a halogen, a substituted or unsubstituted C1 to C10 alkyl group, or a substituted or unsubstituted C3 to C20 cycloalkyl group, or a substituted or unsubstituted C3 to C20 heterocycloalkyl group, and R³ to R⁶ may each independently be hydrogen, a hydroxy group, a halogen, a substituted or unsubstituted C1 to C10 alkoxy group, a substituted or unsubstituted C1 to C10 alkyl group, or a combination thereof.

In some embodiments, the compound represented by Chemical Formula 3 may be represented by any one selected from among Chemical Formula 3-2 to Chemical Formula 3-13.

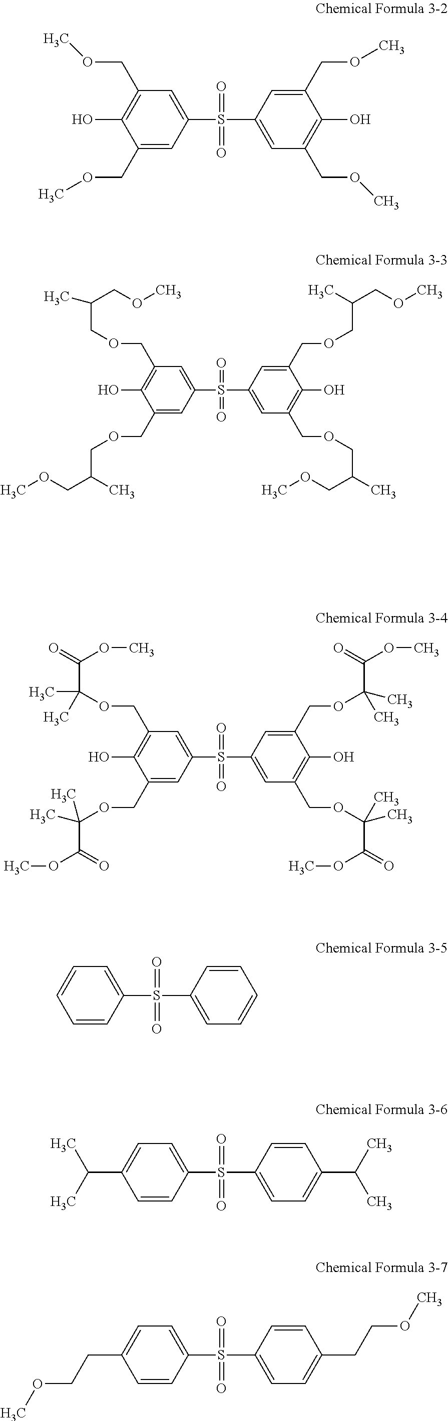

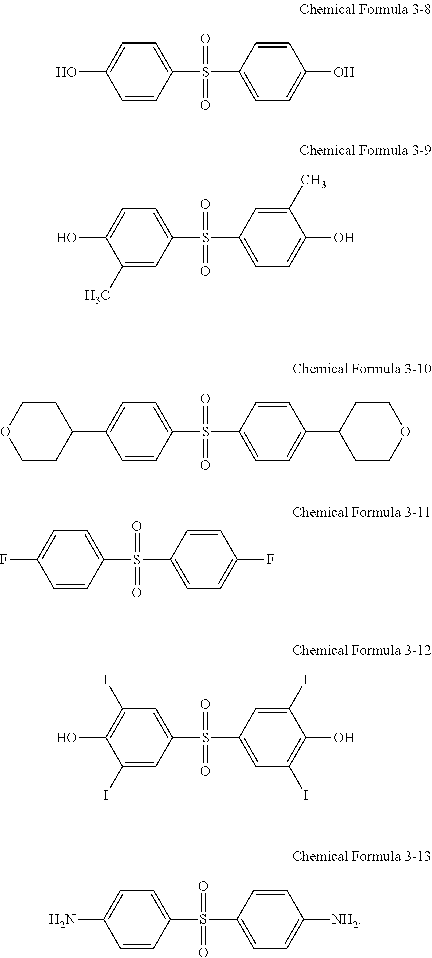 [SMILES: O=S(=O)(c1ccc(O)cc1)c1ccc(O)cc1 ; Cc1cc(S(=O)(=O)c2ccc(O)c(C)c2)ccc1O ; O=S(=O)(c1ccc(C2CCOCC2)cc1)c1ccc(C2CCOCC2)cc1 ; O=S(=O)(c1ccc(F)cc1)c1ccc(F)cc1 ; O=S(=O)(c1cc(I)c(O)c(I)c1)c1cc(I)c(O)c(I)c1 ; Nc1ccc(S(=O)(=O)c2ccc(N)cc2)cc1]

The polymer may have a weight average molecular weight of about 1,000 g/mol to about 300,000 g/mol.

A weight ratio of the polymer and the compound may be about 9:1 to about 2:3.

The polymer may be included in an amount of about 0.1 wt % to about 50 wt % based on the total amount of the resist underlayer composition.

The compound may be included in an amount of about 0.01 wt % to about 20 wt % based on the total amount of the resist underlayer composition.

In one or more embodiments, the resist underlayer composition may further include at least one polymer selected from among an acryl-based resin, an epoxy-based resin, a novolac resin, a glycoluril resin, and a melamine-based resin. In one or more embodiments, the resist underlayer composition may further include an additive of a surfactant, a thermal acid generator, a photoacid generator, a plasticizer, or a combination thereof.

According to one or more embodiments, a method of forming patterns may include forming an etching target layer on a substrate, coating the resist underlayer composition according to one or more embodiments of the present disclosure on the etching target layer to form a resist underlayer, forming a photoresist pattern on the resist underlayer, and sequentially etching the resist underlayer and the etching target layer utilizing the photoresist pattern as an etching mask.

The forming of the photoresist pattern may include forming a photoresist layer on the resist underlayer, exposing the photoresist layer, and developing the photoresist layer.

The forming of the resist underlayer may further include heat treatment at about 100° C. to about 300° C. after coating the resist underlayer composition.

The resist underlayer composition according to one or more embodiments of the present disclosure may provide a resist underlayer having excellent or suitable coating uniformity and improved crosslinking properties without causing pattern collapse of the resist even in a fine patterning process.

In some embodiments, the resist underlayer composition may provide a resist underlayer with improved patterning performance and efficiency by improving sensitivity to an exposure light source.

One or more embodiments may provide a method of forming patterns utilizing the resist underlayer composition.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1-6 are cross-sectional views for explaining a method of forming patterns utilizing a resist underlayer composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Example embodiments of the present disclosure will hereinafter be described in more detail, and may be easily performed by a person skilled in the art. However, this disclosure may be embodied in many different forms and is not construed as limited to the example embodiments set forth herein.

In the drawings, the thickness of layers, films, panels, regions, etc., are exaggerated for clarity and like reference numerals designate like elements throughout the present disclosure, and duplicative descriptions thereof may not be provided. It will be understood that when an element such as a layer, film, region, or substrate is referred to as being “on” another element, it can be directly on the other element or intervening elements may also be present. In contrast, when an element is referred to as being “directly on” another element, there are no intervening elements present.

As utilized herein, when a definition is not otherwise provided, “substituted” may refer to replacement of hydrogen of a compound by a substituent selected from among a halogen (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In some embodiments, two adjacent substituents independently selected

from among the substituted halogen (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid group or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, and C2 to C30 heterocyclic group may be fused to form a ring.

As utilized herein, “aryl group” may refer to a group including at least one hydrocarbon aromatic moiety, and may include hydrocarbon aromatic moieties linked by a single bond and/or hydrocarbon aromatic moieties fused directly or indirectly to provide a non-aromatic fused ring. The aryl group may include a monocyclic, polycyclic, or fused polycyclic (i.e., rings sharing adjacent pairs of carbon atoms) functional group.

As utilized herein, when a definition is not otherwise provided, “hetero” may refer to one including 1 to 3 heteroatoms selected from among N, O, S, Se, and P.

As utilized herein, when a definition is not otherwise provided, “heteroalkyl group” may refer to a group including a heteroatom selected from among N, O, S, P, and Si instead of one or more carbon atoms forming an alkyl group.

As utilized herein, when a definition is not otherwise provided, “heteroaryl group” may refer to an aryl group including at least one heteroatom selected from among N, O, S, P, and Si. Two or more heteroaryl groups may be linked by a sigma bond directly, or when the heteroaryl group includes two or more rings, the two or more rings may be fused. When the heteroaryl group is a fused ring, each ring may include one to three heteroatoms.

In one or more embodiments, the substituted or unsubstituted aryl group and/or a substituted or unsubstituted heteroaryl group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, a substituted or unsubstituted pyridoindolyl group, a substituted or unsubstituted benzopyridooxazinyl group, a substituted or unsubstituted benzopyridothiazinyl group, a substituted or unsubstituted 9,9-dimethyl-9,10-dihydroacridinyl group, a combination thereof, or a combined fused ring of the foregoing groups, but embodiments of the present disclosure are not limited thereto.

As utilized herein, when specific definition is not otherwise provided, “combination” may refer to mixing or copolymerization.

In some embodiments, “polymer” may include both (e.g., simultaneously) an oligomer and a polymer.

As utilized herein, when specific definition is not otherwise provided, the “weight average molecular weight” is measured by dissolving a powder sample in tetrahydrofuran (THF) and then utilizing 1200 series Gel Permeation Chromatography (GPC) of Agilent Technologies (column is Shodex Company LF-804, standard sample is Shodex company polystyrene).

In some embodiments, as utilized herein, when specific definition is not otherwise provided, ‘*’ indicates a linking point of a structural unit of a compound or a compound moiety.

As utilized herein, the terms “and/or” and “or” may include any and all combinations of one or more of the associated listed items. Expressions such as “at least one of,” when preceding a list of elements, modify the entire list of elements and do not modify the individual elements of the list.

Singular expressions may include plural expressions unless the context clearly indicates otherwise. Hereinafter, it will be further understood that the terms “comprise”, “include” or “have,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the semiconductor industry, there is a constant trend to reduce a size of chips. In order to respond to this trend, a resist pattern in lithography should have a line width reduced to several tens of nanometers, wherein a pattern formed in this way is transferred to a lower layer material by etching a lower substrate. However, when a size of the resist pattern becomes small, because an aspect ratio of a resist capable of keeping the line width is limited, the resist may not have sufficient resistance in the etching. Accordingly, when a resist material is utilized to be thin, the substrate for etching is thick, and the pattern is formed to be deep, and/or the like, a resist underlayer has been utilized to compensate for this.

The resist underlayer is required to be thinner, as the resist becomes thinner, but should not collapse the pattern of the photoresist despite the thinness and also exhibit excellent or suitable close contacting property with the photoresist. In addition, a resist underlayer composition should be able to be coated to be uniformly thin on a wafer, and a resist underlayer formed thereof should have excellent or suitable pattern-forming property. In order to achieve these requirements, sensitivity of the resist underlayer should be improved.

To provide a resist underlayer having these required characteristics, one or more embodiments of the present disclosure provide a composition including a polymer including a specific structural unit or a compound with a specific structure. As a result, the composition has been confirmed to form a resist underlayer exhibiting improved close contacting property with the photoresist, improved film density and concurrently (e.g., simultaneously) and improved sensitivity to an exposure light source, and thus excellent or suitable pattern-forming property.

When the resist underlayer composition according to one or more embodiments of the present disclosure is coated under a photoresist and formed into a film, close contacting property between the film and the photoresist may be improved and thus prevent or reduce the resist pattern from collapsing during a fine patterning process.

In one or more embodiments, the resist underlayer composition may include a polymer including a structural unit represented by Chemical Formula 1, a structural unit represented by Chemical Formula 2, or a combination thereof; a compound represented by Chemical Formula 3; and a solvent.

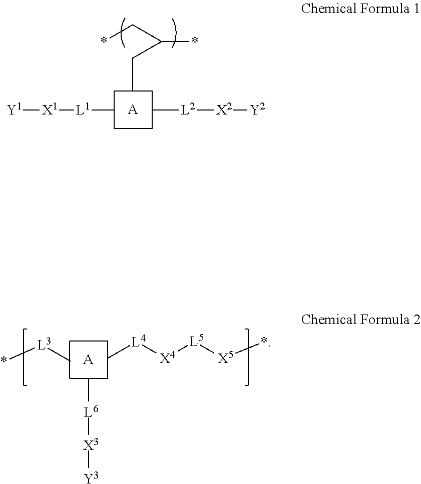

In Chemical Formula 1 and Chemical Formula 2,

A may be a cyclic group represented by any one selected from among Chemical Formula A-1 to Chemical Formula A-3,

L¹ to L⁶ may each independently be a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,

X¹ to X⁵ may each independently be a single bond, —O—, —S—, —S(═O)—, —S(═O)₂—, —C(═O)—, —(CO)O—, —O(CO)O—, —NR′— (wherein, R′ is hydrogen, deuterium, or a C1 to C10 alkyl group), or a combination thereof, and

Y¹ to Y³ may each independently be a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and

* is a linking point;

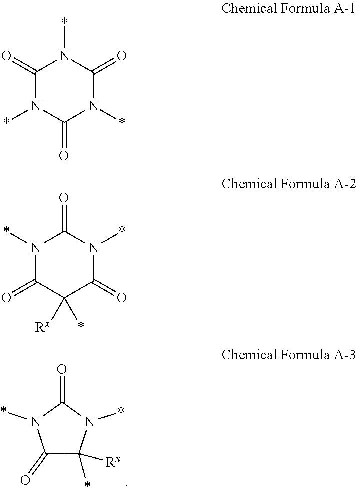

In Chemical Formula A-1 to Chemical Formula A-3,

R^{x} may be hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and

* is a linking point;

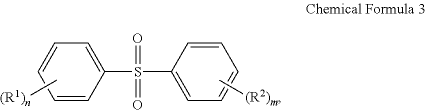

wherein, in Chemical Formula 3,

R¹ and R² may each independently be a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof, and

n and m may each independently be integers of 0 to 5.

Because the structural unit represented by Chemical Formulas 1 and 2 includes a heterocyclic ring including a nitrogen atom in the ring, sp²-sp² interaction (e.g., bonding) between polymers may be enabled, and thus may have a high electron density. As a result, a density of the thin film may be improved to implement a film having a dense structure in the form of an ultra-thin film, and it may have an effect of improving light absorption efficiency during exposure of the resist underlayer composition. When the resist underlayer is formed utilizing the resist underlayer composition, second electrons may be additionally generated during the photo process, and the additionally generated second electrons affect the photoresist during the photo process to maximize or increase the acid generation efficiency. Consequently, sensitivity of the photoresist may be improved by increasing a photo-processing speed of the photoresist.

In some embodiments, because the resist underlayer composition includes the compound represented by Chemical Formula 3, sensitivity to an exposure light source may be improved, and thus patterning performance and efficiency of the photoresist may be improved. For example, the time of the etching process may be shortened, and the pattern may be formed clearly while saving energy.

In one or more embodiments, A of Chemical Formula 1 and Chemical Formula 2 may be represented by Chemical Formula A-1, Chemical Formula A-2, or a combination thereof. In some embodiments, in Chemical Formula A-2, R^{x} may be hydrogen, a substituted or unsubstituted C1 to C10 alkyl group, a substituted or unsubstituted C2 to C10 alkenyl group, or a substituted or unsubstituted C2 to C10 alkynyl group, and in Chemical Formula A-1 and Chemical Formula A-2, and * is a linking point.

In one or more embodiments, L¹ to L⁶ of Chemical Formula 1 and Chemical Formula 2 may each independently be a single bond, a substituted or unsubstituted C1 to C10 alkylene group, a substituted or unsubstituted C1 to C10 heteroalkylene group, or a combination thereof,

X¹ to X⁵ may each independently be a single bond, —O—, —S—, —C(═O)—, —(CO)O—, —O(CO)O—, or a combination thereof, and

Y¹ to Y³ may each independently be a substituted or unsubstituted C1 to C10 alkyl group, a substituted or unsubstituted C2 to C10 alkenyl group, a substituted or unsubstituted C1 to C10 heteroalkyl group, a substituted or unsubstituted C1 to C10 heteroalkenyl group, a substituted or unsubstituted C3 to C20 cycloalkyl group, a substituted or unsubstituted C2 to C20 heterocycloalkyl group, or a combination thereof.

In one or more embodiments, R¹ and R² of Chemical Formula 3 may each independently be a hydroxy group, a halogen, a substituted or unsubstituted C1 to C10 alkoxy group, a substituted or unsubstituted C1 to C10 alkyl group, or a combination thereof. For example, the substituted or unsubstituted C1 to C10 alkyl group is a methyl group, an ethyl group, a propyl group, a butyl group, a pentyl group, a hexyl group, a heptyl group, an octyl group, a nonyl group, or a decyl group, for example, a methyl group, an ethyl group, a propyl group, a butyl group, or a pentyl group. The alkyl group may be substituted, for example, an alkyl group substituted with a hydroxy group, an alkoxy group, or a halogen, for example, a methyl group substituted with a methoxy group or an ethoxy group, for example, an ethyl group substituted with a methoxy group or an ethoxy group, for example, a methyl group, an ethyl group, or a propyl group substituted with a hydroxyl group, for example, a methyl group, an ethyl group, or a propyl group, substituted with fluorine (F) or iodine (I). Depending on the type or kind of R¹ and R², the compound represented by Chemical Formula 3 may be, for example, a photoactive compound, for example, a crosslinking agent.

In one or more embodiments, n and m in Chemical Formula 3 may each independently be an integer of 0 to 5, for example, 0 to 4, for example, 0 to 3.

In some embodiments, the compound represented by Chemical Formula 3 may be represented by Chemical Formula 3-1.

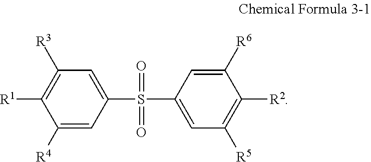

In Chemical Formula 3-1,

R¹ to R⁶ may each independently be hydrogen, a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof.

In some embodiments, the compound represented by Chemical Formula 3 is represented by any one selected from among Chemical Formula 3-2 to Chemical Formula 3-13.

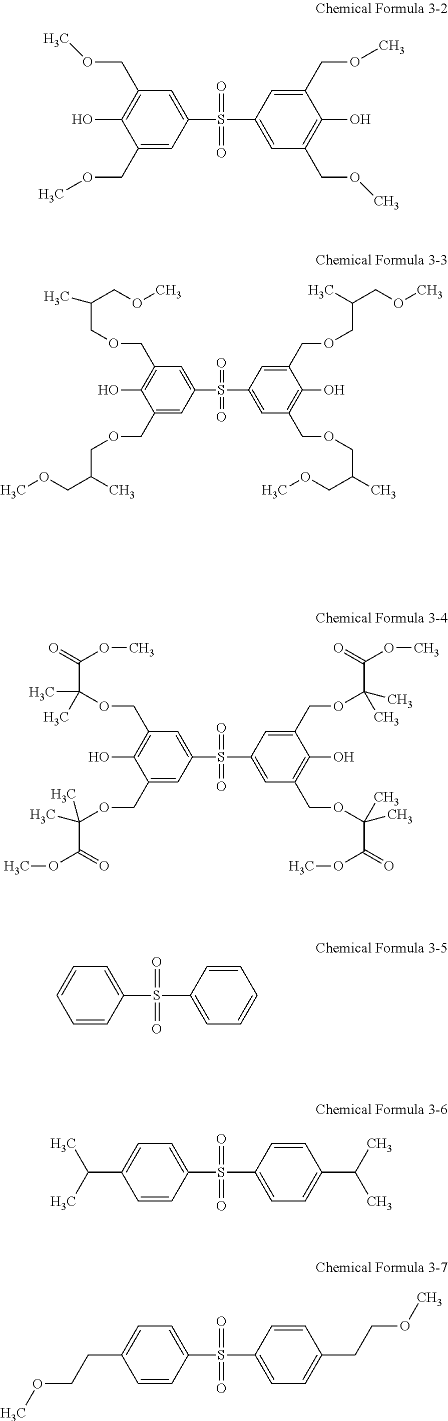

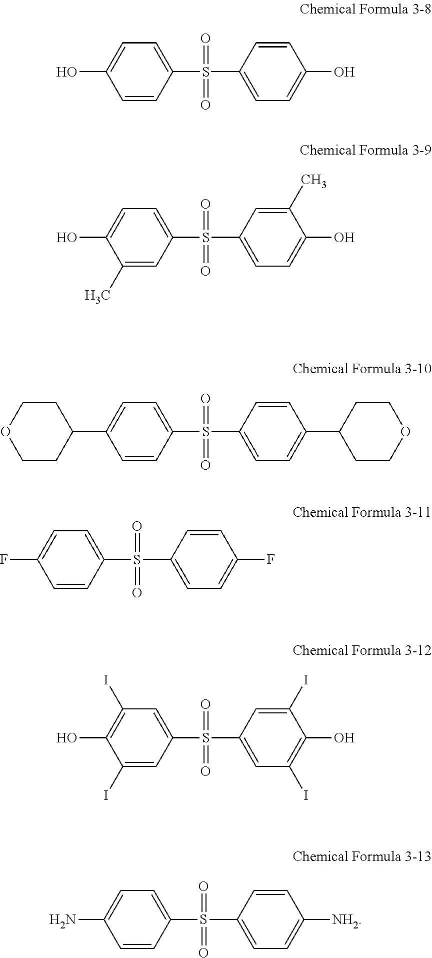 [SMILES: O=S(=O)(c1ccc(O)cc1)c1ccc(O)cc1 ; Cc1cc(S(=O)(=O)c2ccc(O)c(C)c2)ccc1O ; O=S(=O)(c1ccc(C2CCOCC2)cc1)c1ccc(C2CCOCC2)cc1 ; O=S(=O)(c1ccc(F)cc1)c1ccc(F)cc1 ; O=S(=O)(c1cc(I)c(O)c(I)c1)c1cc(I)c(O)c(I)c1 ; Nc1ccc(S(=O)(=O)c2ccc(N)cc2)cc1]

In one or more embodiments, the polymer may have a weight average molecular weight of about 1,000 g/mol to about 300,000 g/mol. In some embodiments, the polymer may have a weight average molecular weight of about 2,000 g/mol to about 300,000 g/mol, for example about 2,000 g/mol to about 200,000 g/mol, for example about 2,000 g/mol to about 100,000 g/mol, for example about 2,000 g/mol to about 90,000 g/mol, for example about 2,000 g/mol to about 70,000 g/mol, for example about 2,000 g/mol to about 50,000 g/mol, for example about 2,000 g/mol to about 30,000 g/mol, for example about 2,000 g/mol to about 20,000 g/mol, for example about 2,000 g/mol to about 10,000 g/mol, but embodiments of the present disclosure are not limited thereto. By having a weight average molecular weight in the above range, the carbon content (e.g., amount) and solubility in a solvent of the resist underlayer composition including the polymer may be adjusted and may be enhanced or optimized.

In one or more embodiments, a weight ratio of the polymer to the compound may be about 9:1 to about 2:3. For example, in some embodiments, the weight ratio may be from about 8:2 to about 2:3, for example from about 7:3 to about 2:3, for example from about 6:4 to about 4:6, but embodiments of the present disclosure are not limited thereto. In one or more embodiments, the weight ratio of the polymer to the compound may be in the range of about 9:1 to about 2:3, for example, about 8:1 to about 2:3, for example, about 7:1 to about 2:3, for example, about 6:1 to about 2:3, for example, about 5:1 to about 2:3, for example, about 4:1 to about 2:3, for example, about 3:1 to about 2:3, but embodiments of the present disclosure are not limited thereto. By including the polymer and compound in the composition according to the example embodiments in the above range, a thickness, surface roughness, and planarization degree of the resist underlayer may be adjusted.

In one or more embodiments, the polymer may be included in an amount of about 0.1 wt % to about 50 wt % based on the total weight of the resist underlayer composition. In some embodiments, the polymer may be included in an amount of about 0.1 wt % to about 30 wt %, for example about 0.1 wt % to about 30 wt %, for example about 0.1 wt % to about 20 wt %, for example about 0.3 wt % to about 20 wt %, for example about 0.3 wt % to about 10 wt % based on the total weight of the resist underlayer composition, but embodiments of the present disclosure are not limited thereto. By including the polymer in the composition within the above range, a thickness, surface roughness, and degree of planarization of the resist underlayer film may be adjusted.

In one or more embodiments, the compound may be included in an amount of about 0.01 wt % to about 20 wt % based on the total weight of the resist underlayer composition. In some embodiments, the compound may be included in an amount of about 0.01 wt % to about 15 wt %, for example about 0.01 wt % to about 10 wt %, for example about 0.01 wt % to about 10 wt %, for example about 0.05 wt % to about 10 wt %, for example about 0.05 wt % to about 5 wt %, for example about 0.1 wt % to about 20 wt %, for example about 0.1 wt % to about 15 wt %, for example about 0.1 wt % to about 10 wt % based on the total weight of the resist underlayer composition, but embodiments of the present disclosure are not limited thereto. By including the compound in the composition within the above range, a thickness, surface roughness, and planarization degree of the resist underlayer may be adjusted.

In one or more embodiments, the resist underlayer composition may include a solvent. The solvent is not particularly limited as long as it has sufficient solubility and/or dispersibility for the polymer and compound according to one or more embodiments. The solvent may include, for example propylene glycol, propylene glycol diacetate, methoxypropanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof, but embodiments of the present disclosure are not limited thereto.

In one or more embodiments, the resist underlayer composition may further include at least one polymer selected from among an acryl-based resin, an epoxy-based resin, a novolac resin, a glycoluril-based resin, and a melamine-based resin in addition to the polymer, compound, and solvent, but embodiments of the present disclosure are not limited thereto.

In one or more embodiments, the resist underlayer composition may further include an additive including a surfactant, a thermal acid generator, a photoacid generator, a plasticizer, or a combination thereof.

The surfactant may be utilized to improve (e.g., reducing) coating defects caused by an increase in the solid content (e.g., amount) when forming the resist underlayer, and may be, for example, an alkylbenzenesulfonate salt, an alkylpyridinium salt, a polyethylene glycol, and/or a quaternary ammonium salt, but embodiments of the present disclosure are not limited thereto.

The thermal acid generator may be, for example, an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalenecarbonic acid, and/or the like, or/and benzointosylate, 2-nitrobenzyltosylate, other organic sulfonic acid alkyl esters, but embodiments of the present disclosure are not limited thereto.

The plasticizer is not particularly limited, and one or more suitable plasticizers may be utilized. Non-limiting examples of the plasticizer may include low molecular compounds such as phthalic acid esters, adipic acid esters, phosphoric acid esters, trimellitic acid esters, citric acid esters, and/or the like, polyether compounds, polyester-based compounds, polyacetal compounds, and/or the like.

In some embodiments, the additive may be included in an amount of about 0.001 parts by weight to about 40 parts by weight based on 100 parts by weight of the resist underlayer composition. Within the above range, a solubility may be improved without changing optical properties of the resist underlayer composition.

According to one or more embodiments, a resist underlayer prepared by utilizing the aforementioned resist underlayer composition is provided. The resist underlayer may be formed by coating the aforementioned resist underlayer composition on, for example, a substrate and then curing through a heat treatment process.

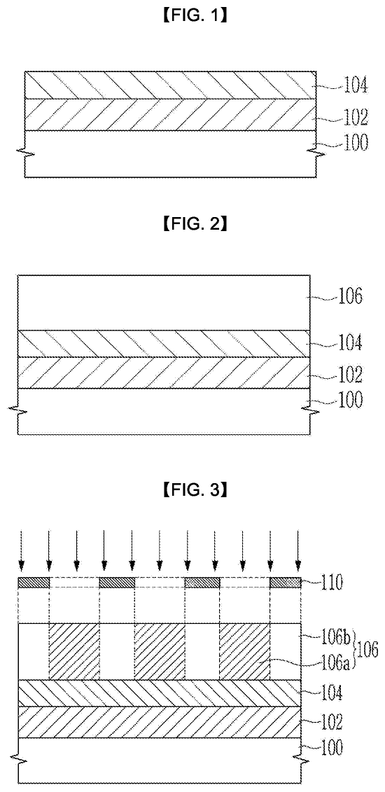

Hereinafter, a method of forming a pattern utilizing the aforementioned resist underlayer composition is described with reference to FIGS. 1 to 6.

FIGS. 1 to 6 are cross-sectional views illustrating a method of forming a pattern utilizing the resist underlayer composition according to one or more embodiments of the present disclosure.

Referring to FIG. 1, an etching target is prepared. The etching target may be a thin film 102 formed on a semiconductor substrate 100. Hereinafter, the etching target is limited to the thin film 102. An entire surface of the thin film 102 is washed to remove impurities and/or the like remaining thereon. In some embodiments, the thin film 102 may be, for example, a silicon nitride layer, a polysilicon layer, or a silicon oxide layer.

Subsequently, the resist underlayer composition of one or more embodiments of the present disclosure is coated on the surface of the cleaned thin film 102 by applying a spin coating method.

Then, the coated resist underlayer composition is dried and baked to form a resist underlayer 104 on the thin film 102. In some embodiments, the baking may be performed at about 100° C. to about 500° C., for example, about 100° C. to about 300° C. A more detailed description of the resist underlayer composition is not provided herein in order to avoid duplication because it has been described in more detail above.

Referring to FIG. 2, a photoresist layer 106 is formed by coating a photoresist on the resist underlayer 104.

Non-limiting examples of the photoresist may be a positive-type or kind photoresist containing a naphthoquinone diazide compound and a novolac resin, a chemically-amplified positive photoresist containing an acid generator capable of dissociating acid through exposure, a compound decomposed under presence of the acid and having increased dissolubility in an alkali aqueous solution, and an alkali soluble resin, a chemically-amplified positive-type or kind photoresist containing an alkali-soluble resin capable of applying a resin increasing dissolubility in an alkali aqueous solution, and/or the like.

Then, a substrate 100 having the photoresist layer 106 is primarily baked. In some embodiments, the primary baking may be performed at about 90° C. to about 120° C.

Referring to FIG. 3, the photoresist layer 106 may be selectively exposed. Exposure of the photoresist layer 106 may be, for example, performed by positioning an exposure mask having a set or predetermined pattern on a mask stage of an exposure apparatus and aligning an exposure mask 110 on the photoresist layer 106. Subsequently, a set or predetermined region of the photoresist layer 106 formed on the substrate 100 selectively reacts with light passing the exposure mask by radiating light into the exposure mask 110.

For example, in some embodiments, the light utilized during the exposure may include short wavelength light such as an activated irradiation i-line having a wavelength of 365 nm, a KrF excimer laser having a wavelength of 248 nm, and/or an ArF excimer laser having a wavelength of 193 nm. In some embodiments, EUV (extreme ultraviolet) having a wavelength of 13.5 nm corresponding to extreme ultraviolet light may be utilized.

The photoresist layer of the exposed region 106a has a relative hydrophilicity compared with the photoresist layer 106b of the unexposed region. Accordingly, the exposed region 106a and non-exposed region 106b of the photoresist layer 106 may have different solubility from each other.

Subsequently, the substrate 100 is secondarily baked. In some embodiments, the secondary baking may be performed at about 90° C. to about 150° C. The exposed region of the photoresist layer becomes easily dissoluble about a set or predetermined solvent due to the secondary baking.

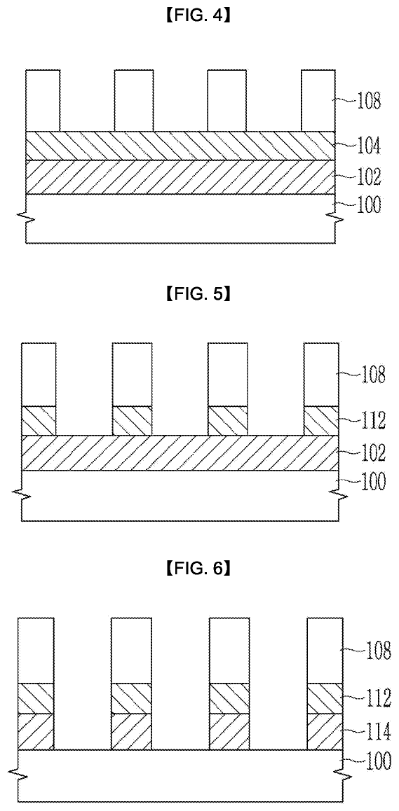

Referring to FIG. 4, the exposed region 106a of the photoresist layer is dissolved and removed by specifically utilizing tetramethyl ammonium hydroxide (TMAH) so that the photoresist layer 106b left after development forms a photoresist pattern 108.

Subsequently, the photoresist pattern 108 is utilized as an etching mask to etch the resist underlayer 104. An organic layer pattern 112 as shown in FIG. 5 is formed by the etching process as described above. In some embodiments, the etching may be, for example, dry etching by utilizing etching gas, and the etching gas may be, for example, CHF₃, CF₄, Cl₂, O₂, or a mixed gas thereof. As described above, because the resist underlayer formed by the resist underlayer composition according to one or more embodiments of the present disclosure has a fast etch rate, a smooth etching process may be performed within a short time.

Referring to FIG. 6, the photoresist pattern 108 is applied as an etching mask to etch the exposed thin film 102. As a result, the thin film is formed into a thin film pattern 114. In the exposure process performed previously, a thin film pattern 114 formed by an exposure process performed utilizing a short wavelength light source such as an activated irradiation i-line (a wavelength of 365 nm), a KrF excimer laser (a wavelength of 248 nm), and/or an ArF excimer laser (a wavelength of 193 nm) may have a width of tens to hundreds of nm, and the thin film pattern 114 formed by the exposure process performed utilizing the EUV light source may have a width of less than or equal to about 20 nm.

Hereinafter, the present disclosure is described in more detail through examples regarding synthesis of the polymer and preparation of a resist underlayer composition including the same. However, the present disclosure is technically not restricted by the following example embodiments.

### SYNTHESIS EXAMPLES

### Synthesis of Polymer

### Synthesis Example 1

In a 500 mL 3-necked round flask, 24.9 g of 1,3-diallyl-5-(2-hydroxyethyl) isocyanurate, 7.4 g of mercapto ethanol, 0.7 g of AIBN (azobisisobutyronitrile), and 48 g of N,N-dimethyl formamide (DMF) were put (placed therein), and a condenser was connected thereto. After conducting a reaction at 80° C. for 16 hours, the reaction solution was cooled to room temperature. Subsequently, the reaction solution was added dropwise to a 1 L wide-mouth bottle containing 800 g of water, while stirred, forming a gum, which was dissolved in 80 g of tetrahydrofuran (THF). The dissolved resin solution was treated with toluene to form precipitates but remove single and small molecules. Finally, 10 g of a polymer represented by Chemical Formula 1-1 (weight average molecular weight (Mw)=10,500 g/mol) was obtained.

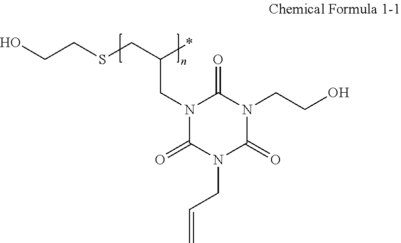

### Synthesis Example 2

In a 500 mL 3-necked round flask, 24.9 g of 1,3,5-triallyl-1,3,5-triazinane-2,4,6-trione, 7.4 g of mercapto ethanol, 0.7 g of AIBN (azobisisobutyronitrile), and 48 g of N,N-dimethyl formamide (DMF) were put, and a condenser was connected thereto. After conducting a reaction at 80° C. for 16 hours, the reaction solution was cooled to room temperature. The reaction solution was added dropwise to a 1 L wide-mouthed bottle containing 800 g of water to produce gum, which was dissolved in 80 g of tetrahydrofuran (THF). The dissolved resin solution was treated with toluene to form precipitates but remove single and low molecules. Finally, 10 g of a polymer (weight average molecular weight (Mw)=8,000 g/mol) having a structural unit represented by Chemical Formula 1-2.

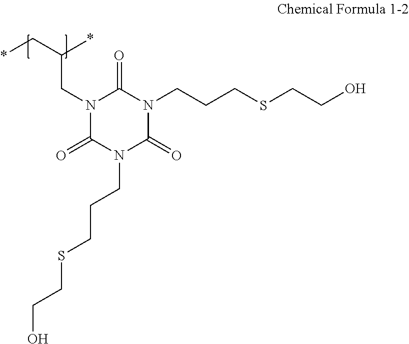

### Synthesis Example 3

In a 250 mL four-necked flask, 20 g of 1,3-diallyl-5,5-dimethyl-1,3-diazinane-2,4,6(1H,3H,5H)-trione, 8.4 g of 2,3-dimercapto-1-propanol, 0.5 g of azobisisobutyronitrile (AIBN), and 50 g of N,N-dimethyl formamide were put to prepare a reaction solution, and a condenser was connected thereto. The reaction solution was heated at 60° C. for 5 hours to conduct a reaction and cooled to room temperature. Subsequently, the reaction solution was added dropwise to a beaker containing 300 g of distilled water, while stirred, forming gum, which was dissolved in 30 g of tetrahydrofuran (THF). Finally, the dissolved resin solution was treated with toluene to form precipitates but remove single and low molecules, obtaining a polymer (weight average molecular weight (Mw)=3,700 g/mol) having a structural unit represented by Chemical Formula 2-1.

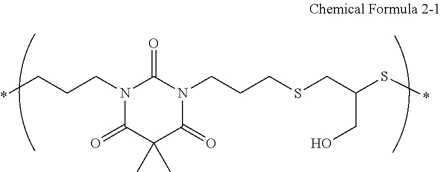

### Synthesis Example 4

In an 1 L 2-necked round flask, 148.6 g (0.5 mol) of 1,3,5-triglycidyl isocyanurate, 60.0 g (0.4 mol) of 2,2′-thiodiacetic acid, 9.1 g of benzyl triethyl ammonium chloride, and 350 g of N,N-dimethylformamide were put, and a condenser was connected thereto. The reaction solution was heated to 100° C., reacted for 8 hours, and cooled to room temperature (23° C.). Subsequently, the reaction solution was transferred to a 1 L wide-mouth bottle and then, three times washed with hexane and subsequently, with purified water. The obtained gum resin was completely dissolved in 80 g of THF and then, slowly, added dropwise to 700 g of toluene. Subsequently, the solvent was removed to obtain a polymer (weight average molecular weight (Mw)=9,100 g/mol) having a structural unit represented by Chemical Formula 2-2.

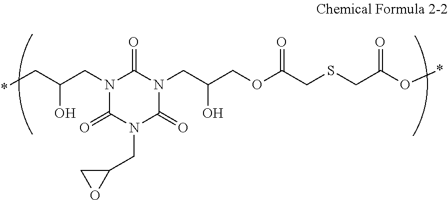

### Synthesis Example 5

In a 250 mL four-necked flask, 20 g of 11,3-diallyl-5-(2,2-dimethyl)-isocyanurate, 6.0 g of ethane-1,2-dithiol, 1 g of azobisisobutyronitrile (AIBN), and 50 g of N,N-dimethyl formamide were put to prepare a reaction solution, and a condenser was connected thereto. The reaction solution was heated at 50° C. for 5 hours to conduct a reaction, and 10 g of 3,4-difluorobenzyl mercaptan and 1 g of azobisisobutyronitrile (AIBN) were added thereto and then, additionally reacted for 2 hours and cooled to room temperature. Subsequently, the reaction solution was added dropwise to a beaker containing 300 g of distilled water, while stirred, to produce gum, which was dissolved in 30 g of tetrahydrofuran (THF). The dissolved resin solution was treated with toluene to form precipitates but remove single and low molecules, obtaining a polymer represented by Chemical Formula 2-3 (weight average molecular weight (Mw)=5,500 g/mol).

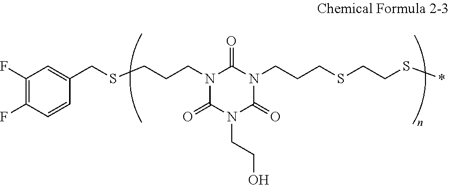

### Synthesis of Compound

### Synthesis Example 6

In a 500 mL flask, 10 g of 4,4′-sulfonyldiphenol, 24 g of diethylamine, and 10 g of paraformaldehyde with 20 g of distilled water were put, reacted at 85° C. for 10 hours or more, and cooled. The cooled reactant was added to 100 g of toluene and then, mixed with 100 g of water after stirring, and after three times repeatedly removing water layer-separated therefrom, toluene was removed therefrom, obtaining a compound represented by Chemical Formula 3-2a.

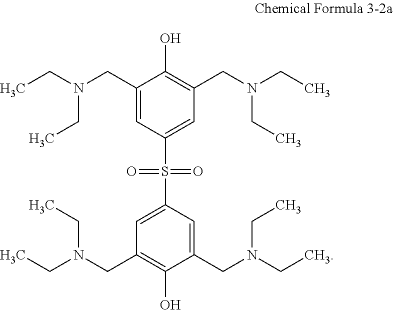 [SMILES: CCN(CC)Cc1cc(S(=O)(=O)c2cc(CN(CC)CC)c(O)c(CN(CC)CC)c2)cc(CN(CC)CC)c1O]

In a 500 mL flask, 21 g of the compound represented by Chemical Formula 3-2a and 30 g of acetic anhydride were put and then, reacted at 85° C. for 18 hours and cooled. After removing all the solvent through evaporation in vacuum, a reactant obtained therefrom was thoroughly dissolved in 20 g of methanol and then, frozen-stored, and recrystallized. The recrystallized powder was filtered and dried, obtaining a compound represented by Chemical Formula 3-2b.

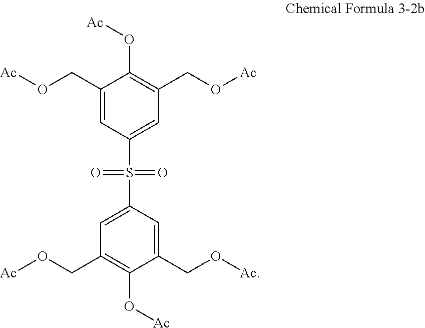 [SMILES: CC(=O)OCc1cc(S(=O)(=O)c2cc(COC(C)=O)c(OC(C)=O)c(COC(C)=O)c2)cc(COC(C)=O)c1OC(C)=O]

In a 500 mL flask, 19 g of the compound represented by Chemical Formula 3-2b, 140 g of methanol, and 30 g of sulfuric acid were put and then, stirred, reacted at 65° C. for 3 days, and cooled. When a reaction was completed, the flask was stored under freezing conditions for 24 hours to form crystals, which were filtered to obtain powder. The powder was several times washed with water, neutralized, and dried, obtaining a compound represented by Chemical Formula 3-2.

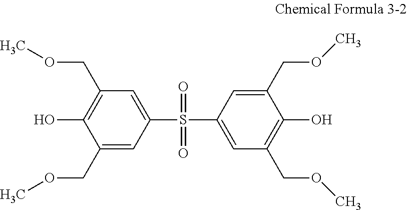

### Synthesis Example 7

20 g of the compound represented by Chemical Formula 3-2b according to Synthesis Example 6, 150 g of PGME (propylene glycol monomethyl ether), and 30 g of sulfuric acid were put and then, well stirred, reacted at 65° C. for 3 days, and cooled. When a reaction was completed, the flask was stored under freezing conditions for 24 hours to layer-separate the liquid compound and the solvent. After removing the solvent in the upper layer, the other layer was several times repeatedly washed by adding water thereto and neutralized by removing the water therefrom and then, concentrated, and dried, finally obtaining a compound represented by Chemical Formula 3-3.

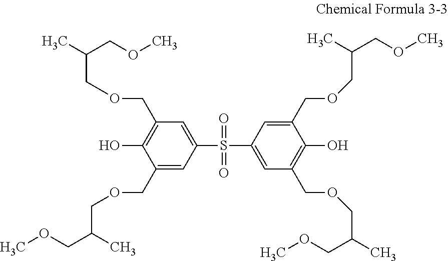

### Synthesis Example 8

In a 250 mL flask, 7.5 g of 4,4′-sulfonyldiphenol, 22 g of p-toluenesulfonic acid, and 90 g of acetonitrile were put and then, stirred for 30 minutes, and 30 g of N-iodosuccinimide was added thereto and then, reacted at room temperature for 10 hours. Subsequently, 400 g of ethyl acetate and 300 g of distilled water were added to the reaction solution and stirred, 100 g of a 10% sodium sulfite aqueous solution was additionally added thereto and then, sufficiently stirred to separate layers, and after removing a water layer therefrom, the other layer was three times repeatedly treated by additionally adding 300 g of distilled water thereto, stirring the mixture, and removing the water. Then, precipitates were formed therein by utilizing hexane and then, filtered, and dried, obtaining a compound represented by Chemical Formula 3-12.

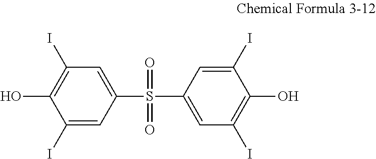 [SMILES: O=S(=O)(c1cc(I)c(O)c(I)c1)c1cc(I)c(O)c(I)c1]

### PREPARATION OF RESIST UNDERLAY COMPOSITION

### Examples 1 to 8 and Comparative Examples 1 to 2

### Example 1

A resist underlayer composition of Example 1 was prepared by completely dissolving 0.5 g of the polymer prepared from Synthesis Example 1 and the compound finally obtained from Synthesis Example 6 in a ratio (e.g., amount) of 100:30, 0.1 g of PD1174 (crosslinking agent, TCI Chemical Industry), and 0.01 g of pyridinium para-toluenesulfonate (PPTS) in 90 g of propylene glycol monomethylether and 5 g of ethyl lactate and then, additionally diluting the solution with the solvents.

### Example 2

A resist underlayer composition of Example 2 was prepared in substantially the same manner as in Example 1 except that the compound of Synthesis Example 7 was utilized instead of the compound of Synthesis Example 6.

### Example 3

A resist underlayer composition of Example 3 was prepared in substantially the same manner as in Example 1 except that the compound of Synthesis Example 8 was utilized instead of the compound of Synthesis Example 6.

### Example 4

A resist underlayer composition of Example 4 was prepared in substantially the same manner as in Example 1 except that a compound represented by Chemical Formula 3-8 (4,4′-sulfonyldiphenol, Sigma-Aldrich Corporation) was utilized instead of the compound of Synthesis Example 6.

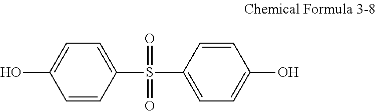 [SMILES: O=S(=O)(c1ccc(O)cc1)c1ccc(O)cc1]

### Example 5

A resist underlayer composition of Example 5 was prepared in substantially the same manner as in Example 1 except that a compound represented by Chemical Formula 3-11 (4,4′-sulfonylbis(fluorobenzene); Sigma-Aldrich Corporation) was utilized instead of the compound of Synthesis Example 6.

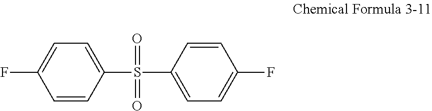 [SMILES: O=S(=O)(c1ccc(F)cc1)c1ccc(F)cc1]

### Example 6

A resist underlayer composition of Example 6 was prepared in substantially the same manner as in Example 2 except that the polymer of Synthesis Example 2 was utilized instead of the polymer of Synthesis Example 1.

### Example 7

A resist underlayer composition of Example 7 was prepared in substantially the same manner as in Example 3 except that the polymer of Synthesis Example 2 was utilized instead of the polymer of Synthesis Example 1.

### Example 8

A resist underlayer composition of Example 8 was prepared in substantially the same manner as in Example 4 except that the polymer of Synthesis Example 2 was utilized instead of the polymer of Synthesis Example 1.

### Example 9

A resist underlayer composition of Example 9 was prepared in substantially the same manner as in Example 2 except that the polymer of Synthesis Example 3 was utilized instead of the polymer of Synthesis Example 1.

### Example 10

A resist underlayer composition of Example 10 was prepared in substantially the same manner as in Example 5 except that the polymer of Synthesis Example 4 was utilized instead of the polymer of Synthesis Example 1.

### Example 11

A resist underlayer composition of Example 11 was prepared in substantially the same manner as in Example 5 except that the polymer of Synthesis Example 5 was utilized instead of the polymer of Synthesis Example 1.

### Comparative Example 1

A resist underlayer composition of Comparative Example 1 was prepared by completely dissolving 0.5 g of the polymer of Synthesis Example 3, 0.1 g of PD1174 (crosslinking agent; TCI Chemical Industry), and 0.01 g of pyridinium para-toluenesulfonate (PPTS) in 90 g of propylene glycol monomethylether and 5 g of ethyl lactate and additionally diluting the solution with the solvents.

### Comparative Example 2

A resist underlayer composition of Comparative Example 2 was prepared in substantially the same manner as in Comparative Example 1 except that the polymer of Synthesis Example 4 was utilized instead of the polymer of Synthesis Example 3.

### Evaluation of Coating Uniformity

The compositions according to Examples 1 to 11 and Comparative Examples 1 to 2 were respectively taken by 2 mL, coat on an 8-inch wafer, spin-coated at a main speed of 1,500 rpm for 20 seconds by utilizing an auto track (ACT-8, TEL (Tokyo Electron Limited)), and cured at 205° C. for 60 seconds, forming 50 Å-thick thin layers.

Each thickness at 51 points along a horizontal axis was measured to evaluate coating uniformity, and the results are shown in Table 1. It refers to that as a coating uniformity value is small, coating uniformity is excellent or suitable.

* Coating uniformity (Å)=Max. thickness−Min. thickness at 51 points in the wafer

TABLE 1

| | Coating uniformity (@ thickness 50 Å) | |
|---|---|---|
| Example 1 | 5 | Å |
| Example 2 | <2 | Å |
| Example 3 | <2 | Å |
| Example 4 | <2 | Å |
| Example 5 | 3 | Å |
| Example 6 | <2 | Å |
| Example 7 | <2 | Å |
| Example 8 | <2 | Å |
| Example 9 | <2 | Å |
| Example 10 | 5 | Å |
| Example 11 | 4 | Å |
| Comparative Example 1 | 5 | Å |
| Comparative Example 2 | 6 | Å |

Referring to Table 1, the resist underlayer compositions according to Examples 1 to 11 exhibited a coating uniformity of less than 6 Å, which indicates that they have excellent or suitable coating uniformity.

### Evaluation of Exposure Characteristics

The compositions of Examples 1 to 9 and Comparative Examples 1 to 2 were respectively coated in a spin-on coating method and then, heat-treated on a hot plate at 205° C. for 60 seconds to form about 50 Å-thick resist underlayers. Subsequently, on the resist underlayers, a photoresist solution was coated in the spin-on coating method and then, heat-treated on a hot plate at 110° C. for 1 minute to form photoresist layers. The photoresist layers were exposed in a range of 200 μC/cm 2 to 1700 μC/cm² by utilizing an e-beam exposer (Elionix Inc.) and then, heat-treated at 110° C. for 60 seconds. Subsequently, the photoresist layers were developed with an aqueous solution of 2.38 mass % TMAH at 23° C. and then, rinsed with pure water for 15 seconds to form a photoresist pattern of 50 nm line and space (L/S). Then, an optimal or suitable exposure dose of the photoresist pattern was evaluated, and the results are shown in Table 2. Herein, an exposure dose for developing a 50 nm line and space pattern size with a ratio of 1:1 was regarded as optimum energy (Eop, μC/cm²), wherein the smaller the value, the better the sensitivity. In addition, a minimum size at which the line pattern was well formed without connecting or collapsing lines, is called to be minimum CD, wherein the smaller the size of the pattern, the better the resolution.

TABLE 2

| | Exposure dose (Eop, μC/cm²) | Minimum CD (nm) |
|---|---|---|
| Example 1 | 395 | 49 |
| Example 2 | 384 | 48 |
| Example 3 | 358 | 45 |
| Example 4 | 355 | 46 |
| Example 5 | 361 | 45 |
| Example 6 | 380 | 48 |
| Example 7 | 372 | 46 |
| Example 8 | 375 | 48 |
| Example 9 | 389 | 48 |
| Comparative | 50 nm pattern was not formed | 54 |
| Example 1 | | |
| Comparative | 50 nm pattern was not formed | 55 |
| Example 2 | | |

Referring to Table 2, when the compositions according to Examples 1 to 9 were respectively formed into resist underlayers, a fine pattern (50 nm L/S) was obtained, compared with the compositions according to Comparative Examples 1 to 2. Accordingly, the resist underlayer composition according to examples turned out to form a photoresist pattern with much more excellent or suitable sensitivity, compared with the compositions according to the comparative examples.

Hereinbefore, the certain embodiments of the present disclosure have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

Description of Symbols

| | |
|---|---|
| 100: substrate | 102: thin film |
| 104: resist underlayer | 106: photoresist layer |
| 108: photoresist pattern | 110: mask |
| 112: organic layer pattern | 114: thin film pattern |

What is claimed is:

1. A resist underlayer composition comprising:
a polymer comprising a structural unit represented by Chemical Formula 1, a structural unit represented by Chemical Formula 2, or a combination thereof;
a compound represented by Chemical Formula 3; and
a solvent: 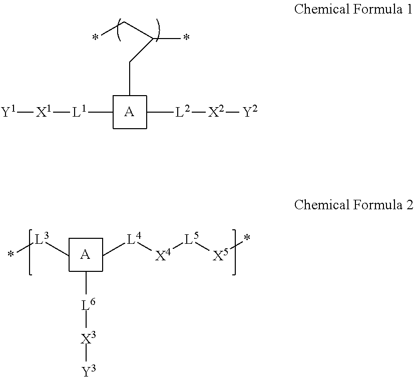
wherein, in Chemical Formula 1 and Chemical Formula 2,
A is a cyclic group represented by any one selected from among Chemical Formula A-1 to Chemical Formula A-3,
L¹ to L⁶ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond, —O—, —S—, —S(═O)—, —S(═O)₂—, —C(═O)—, —(CO)O—, —O(CO)O—, —NR′— (wherein, R′ is hydrogen, deuterium, or a C1 to C10 alkyl group), or a combination thereof,
Y¹ to Y³ are each independently a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is a linking point; 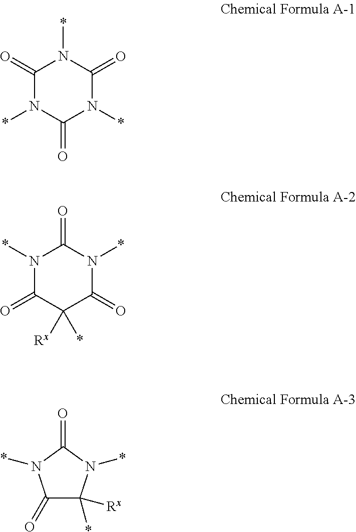
wherein, in Chemical Formula A-1 to Chemical Formula A-3,
R^{x} is hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is a linking point; 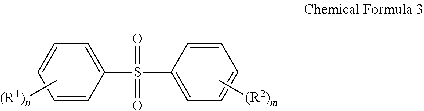
wherein, in Chemical Formula 3,
R¹ and R² are each independently a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof, and
n and m are each independently integers of 0 to 5.

2. The resist underlayer composition of claim 1, wherein A of Chemical Formula 1 and Chemical Formula 2 is represented by Chemical Formula A-1, Chemical Formula A-2, or a combination thereof: 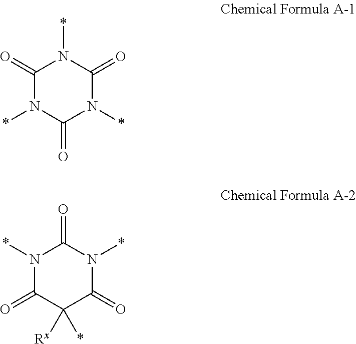
wherein, in Chemical Formula A-2, R^{x} is hydrogen, a substituted or unsubstituted C1 to C10 alkyl group, a substituted or unsubstituted C2 to C10 alkenyl group, or a substituted or unsubstituted C2 to C10 alkynyl group, and
in Chemical Formula A-1 and Chemical Formula A-2, * is a linking point.

3. The resist underlayer composition of claim 1, wherein L¹ to L⁶ of Chemical Formula 1 and Chemical Formula 2 are each independently a single bond, a substituted or unsubstituted C1 to C10 alkylene group, a substituted or unsubstituted C1 to C10 heteroalkylene group, or a combination thereof,
X¹ to X⁵ are each independently a single bond, —O—, —S—, —C(═O)—, —(CO)O—, —O(CO)O—, or a combination thereof, and
Y¹ to Y³ are each independently a substituted or unsubstituted C1 to C10 alkyl group, a substituted or unsubstituted C2 to C10 alkenyl group, a substituted or unsubstituted C1 to C10 heteroalkyl group, a substituted or unsubstituted C1 to C10 heteroalkenyl group, a substituted or unsubstituted C3 to C20 cycloalkyl group, a substituted or unsubstituted C2 to C20 heterocycloalkyl group, or a combination thereof.

4. The resist underlayer composition of claim 1, wherein R¹ and R² of Chemical Formula 3 are each independently a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, or a combination thereof.

5. The resist underlayer composition of claim 1, wherein n and m of Chemical Formula 3 are each independently integers of 0 to 3.

6. The resist underlayer composition of claim 1, wherein the compound represented by Chemical Formula 3 is represented by Chemical Formula 3-1: 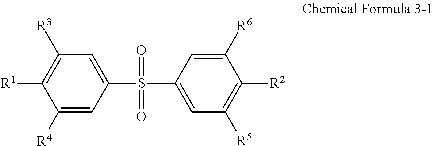
wherein, in Chemical Formula 3-1,
R¹ to R⁶ are each independently hydrogen, a hydroxy group, an amino group, a halogen, a substituted or unsubstituted C1 to C10 alkoxy group, a substituted or unsubstituted C1 to C10 alkyl group, a substituted or unsubstituted C3 to C20 cycloalkyl group, a substituted or unsubstituted C3 to C20 heterocycloalkyl group, a substituted or unsubstituted C6 to C20 aryl group, a substituted or unsubstituted C1 to C20 heteroaryl group, or a combination thereof.

7. The resist underlayer composition of claim 6, wherein R¹ and R² of Chemical Formula 3-1 are each independently a hydroxy group, an amino group, a halogen, a substituted or unsubstituted C1 to C10 alkyl group, or a substituted or unsubstituted C3 to C20 heterocycloalkyl group, and R³ to R⁶ are each independently hydrogen, a hydroxy group, a halogen, a substituted or unsubstituted C1 to C10 alkoxy group, a substituted or unsubstituted C1 to C10 alkyl group, or a combination thereof.

8. The resist underlayer composition of claim 1, wherein the compound represented by Chemical Formula 3 is represented by any one selected from among Chemical Formula 3-2 to Chemical Formula 3-13:

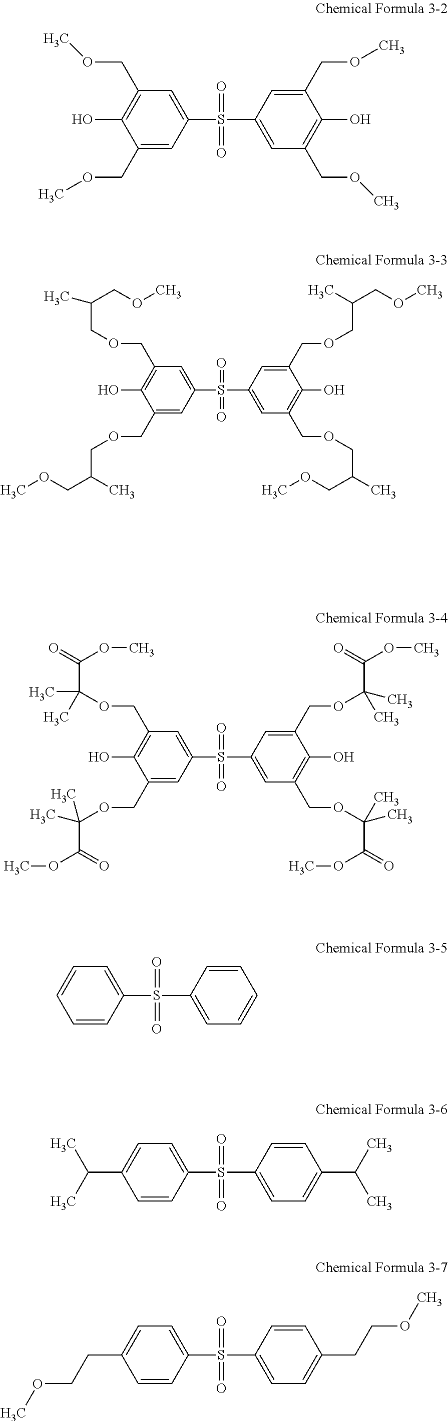

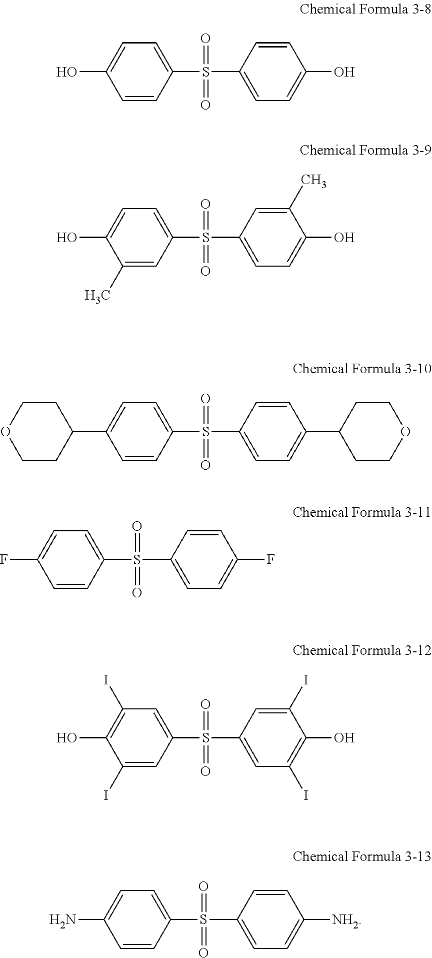 [SMILES: O=S(=O)(c1ccc(O)cc1)c1ccc(O)cc1 ; Cc1cc(S(=O)(=O)c2ccc(O)c(C)c2)ccc1O ; O=S(=O)(c1ccc(C2CCOCC2)cc1)c1ccc(C2CCOCC2)cc1 ; O=S(=O)(c1ccc(F)cc1)c1ccc(F)cc1 ; O=S(=O)(c1cc(I)c(O)c(I)c1)c1cc(I)c(O)c(I)c1 ; Nc1ccc(S(=O)(=O)c2ccc(N)cc2)cc1]

9. The resist underlayer composition of claim 1, wherein the polymer has a weight average molecular weight of about 1,000 g/mol to about 300,000 g/mol.

10. The resist underlayer composition of claim 1, wherein a weight ratio of the polymer and the compound is about 9:1 to about 2:3.

11. The resist underlayer composition of claim 1, wherein the polymer is included in an amount of about 0.1 wt % to about 50 wt % based on the total amount of the resist underlayer composition.

12. The resist underlayer composition of claim 1, wherein the compound is included in an amount of about 0.01 wt % to about 20 wt % based on the total amount of the resist underlayer composition.

13. The resist underlayer composition of claim 1, wherein the resist underlayer composition further comprises at least one polymer selected from among an acryl-based resin, an epoxy-based resin, a novolac resin, a glycoluril resin, and a melamine-based resin.

14. The resist underlayer composition of claim 1, wherein the resist underlayer composition further comprises an additive of a surfactant, a thermal acid generator, a photoacid generator, a plasticizer, or a combination thereof.

15. A method of forming patterns, the method comprising:
applying an etching target layer on a substrate;
coating the resist underlayer composition of claim 1 on the etching target layer to form a resist underlayer;
applying a photoresist pattern on the resist underlayer; and
sequentially etching the resist underlayer and the etching target layer utilizing the photoresist pattern as an etching mask.

16. The method of claim 15, wherein
the applying of the photoresist pattern comprises:
applying a photoresist layer on the resist underlayer;
exposing the photoresist layer; and
developing the photoresist layer.

17. The method of claim 15, wherein the resist underlayer is formed by heat treatment at about 100° C. to about 300° C. after the coating of the resist underlayer composition.

18. The method of claim 15, wherein the polymer has a weight average molecular weight of about 1,000 g/mol to about 300,000 g/mol.

19. The method of claim 15, wherein the polymer is included in an amount of about 0.1 wt % to about 50 wt % based on the total amount of the resist underlayer composition.

20. The method of claim 15, wherein the compound is included in an amount of about 0.01 wt % to about 20 wt % based on the total amount of the resist underlayer composition.
